(19) United States
(12) Patent Application Publication
(10) Pub. No.: US 2008/0164542 A1
(43) Pub. Date: Jul. 10, 2008

(54) METHODS AND SYSTEMS FOR WAFER LEVEL PACKAGING OF MEMS STRUCTURES

(75) Inventors: Xiao Yang, Cupertino, CA (US); Justin Payne, San Jose, CA (US); Yuxiang Wang, Palo Alto, CA (US); Wook Ji, San Jose, CA (US); Ye Wang, Cupertino, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Miradia Inc., Sunnyvale, CA (US)

(21) Appl. No.: 11/969,817

(22) Filed: Jan. 4, 2008

Related U.S. Application Data
(60) Provisional application No. 60/883,744, filed on Jan. 5, 2007.

(51) Int. Cl. H01L 21/48; H01L 23/02

(52) U.S. Cl. 257/415; 438/51; 257/E23.18; 257/E21.499

(57) ABSTRACT

A method of forming a package for a MEMS structure coupled to a substrate includes depositing an encapsulant material on the substrate and patterning the encapsulant material to form a plurality of encapsulated structures. The method also includes depositing a first capping layer on the substrate and forming one or more release hole patterns in the first capping layer. The method further includes removing the encapsulant material and depositing a second capping layer.

### CROSS-REFERENCES TO RELATED APPLICATIONS

The present application claims benefit under 35 U.S.C. § 119(e) of U.S. Provisional Patent Application No. 60/883,744, filed Jan. 5, 2007, entitled “Methods and systems for wafer level packaging of MEMS structures,” the disclosure of which is incorporated herein by reference in its entirety.

### BACKGROUND OF THE INVENTION

This present invention relates generally to manufacturing objects. More particularly, the invention provides a method and structure for hermetically sealing a MEMS structure in a package. Merely by way of example, the invention has been applied to hermetic sealing of a MEMS resonator using a wafer-level packaging process. The method and structure can be applied to other micro-electromechanical system technology as well, for example, other sensors, detectors, and the like.

Micro-electromechanical systems (MEMS) are utilized in a variety of application areas including displays, accelerometers, and sensors. MEMS are generally fabricated using semiconductor processing techniques such as deposition, etching, bonding, and the like. Due to the small scale of these processes, portions of the device are micro-machined to form various components of the MEMS. As a result, various stationary and moveable components of the MEMS structure, both electrical and mechanical, are provided by MEMS fabrication techniques.

The packaging of MEMS structures is generally performed by placing the MEMS structure in an inert environment and gluing a packaging structure to the substrate supporting the MEMS structure. The packaging structure is usually shaped like an open box, which is mounted open side down, providing an open space surrounding the MEMS structure so that the elements of the MEMS structure can move as appropriate to the particular application. The thickness associated with the sides of such a packaging structure result in limitations on the density with which packages are packed. Moreover, some packaging processes perform the packaging of MEMS structures at the device level, with a single packaging structure enclosing a single MEMS structures. Such processes involve considerable time and/or labor to individually seal each MEMS structure in the package.

Thus, there is a need in the art for improved methods and systems for packaging MEMS structures.

### SUMMARY OF THE INVENTION

According to the present invention, techniques for manufacturing objects are provided. More particularly, the invention provides a method and structure for hermetically sealing a MEMS structure in a package. Merely by way of example, the invention has been applied to hermetic sealing of a MEMS resonator using a wafer-level packaging process. The method and structure can be applied to other micro-electromechanical system technology as well, for example, other sensors, detectors, and the like.

According to an embodiment of the present invention, a method of forming a package for a MEMS structure coupled to a substrate is provided. The method includes depositing an encapsulant material on the substrate and patterning the encapsulant material to form a plurality of encapsulated structures. The method also includes depositing a first capping layer on the substrate and forming one or more release hole patterns in the first capping layer. The method further includes removing the encapsulant material and depositing a second capping layer.

According to another embodiment of the present invention, a package for a MEMS structure is provided. The package includes a MEMS structure coupled to a substrate and a cavity region adjacent the MEMS structure and extending to a predetermined distance from the substrate. The package also includes a first sealant layer having a first portion joined to the substrate and a second portion disposed over the cavity region. The package further includes a second sealant layer having a first portion joined to the first portion of the first sealant layer and a second portion joined to the second portion of the first sealant layer.

Numerous benefits are achieved using the present invention over conventional techniques. For example, in an embodiment according to the present invention, the form factor for hermetically sealed MEMS resonator packages is smaller than that provided by conventional techniques. Moreover, embodiments of the present invention utilize well developed integrated circuit processing techniques to fabricate the packaging structure, thereby reducing cost and improving package reliability. Depending upon the embodiment, one or more of these benefits may exist. Various additional objects, features, and advantages of the present invention can be more fully appreciated with reference to the detailed description and accompanying drawings that follow.

### BRIEF DESCRIPTION OF THE DRAWINGS

FIG. 1A is a simplified perspective illustration of a portion of a MEMS resonator according to an embodiment of the present invention;

FIG. 1B is a simplified cross-sectional view of the MEMS resonator shown in FIG. 1A;

FIG. 2 is a simplified cross-sectional view of a MEMS package at a first stage of formation according to an embodiment of the present invention;

FIG. 3 is a simplified cross-sectional view of a MEMS package at a second stage of formation according to an embodiment of the present invention;

FIG. 4 is a simplified cross-sectional view of a MEMS package at a third stage of formation according to an embodiment of the present invention;

FIG. 5 is a simplified cross-sectional view of a MEMS package at a fourth stage of formation according to an embodiment of the present invention;

FIG. 6 is a simplified cross-sectional view of a MEMS package at a fifth stage of formation according to an embodiment of the present invention; and

FIG. 7 is a simplified flowchart illustrating a method of fabricating a hermetically sealed package according to an embodiment of the present invention.

### DETAILED DESCRIPTION OF SPECIFIC EMBODIMENTS

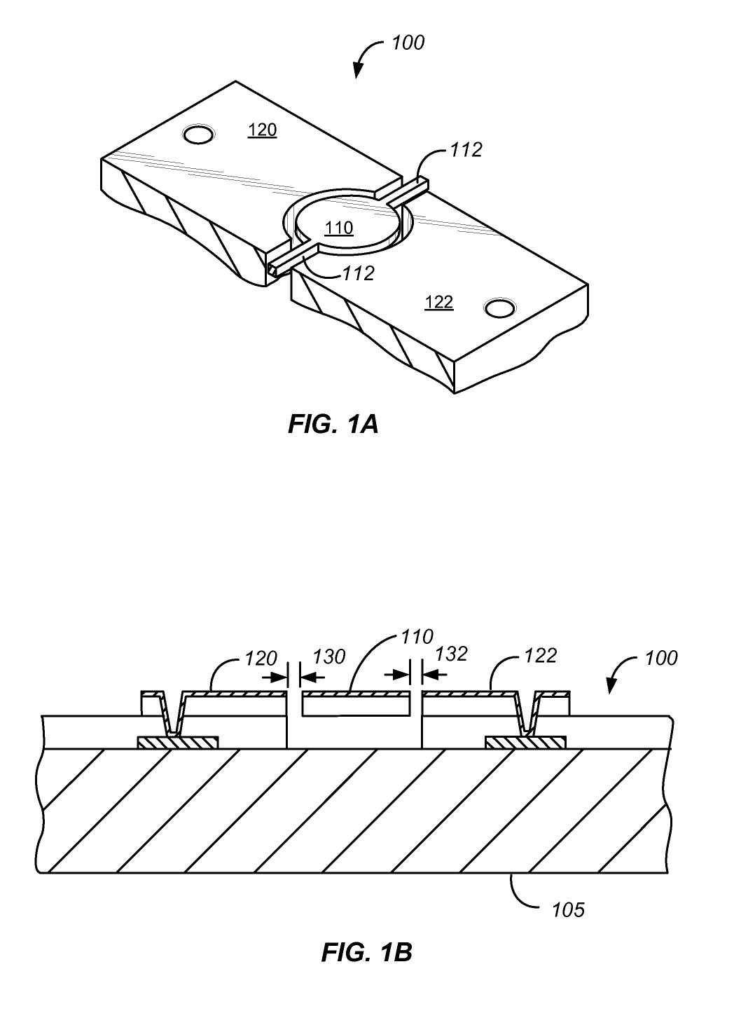

FIG. 1A is a simplified perspective illustration of a portion of a MEMS resonator. The MEMS resonator 100 includes a moveable structure 110 that is mechanically coupled to one or more flexible members 112. The moveable structure 110 is mechanically responsive to electrical signals provided using drive electrode 120. In turn, sense electrode 122 is electrically responsive to mechanical vibrations of the moveable structure 110. Although not illustrated in FIG. 1A, a CMOS substrate provides mechanical support for resonator structure 120. Moreover, the CMOS substrate provides electrical inputs to the resonator structure as well as receives electrical outputs from the resonator structure. Additional discussion related to the CMOS substrate is provided throughout the present specification and more particularly below.

Although the thickness of the moveable member 110 and the flexible members 112 is illustrated as less than the thickness of the electrodes 120/122 in FIG. 1A, this is not required by embodiments of the present invention. In particular embodiments described herein, the moveable member 110, the flexible members, 112, and the electrodes 120/122 are fabricated from a single layer, thereby providing for structures having the same thickness. In other embodiments, additional layers that are deposited or otherwise formed result in structures with different thicknesses as appropriate to the particular applications. The shape of the moveable plate is illustrated as a circle merely by way of example. In other embodiments, other shapes are utilized as appropriate to the particular oscillator application. One of ordinary skill in the art would recognize many variations, modifications, and alternatives

FIG. 1B is a simplified cross-sectional view of the MEMS resonator 100 shown in FIG. 1A. As illustrated in FIG. 1B, the MEMS resonator 100 is coupled to a CMOS substrate 105 that provides mechanical support for the MEMS resonator. As described above, the CMOS substrate 105 includes CMOS circuitry adapted to provide electrical control of the MEMS resonator. In other embodiments, the substrate includes CMOS circuitry adapted to receive electrical signals generated by the MEMS resonator. Thus, embodiments of the present invention provide for applications that include sensors, detectors, timing devices, and the like. As illustrated in FIG. 1B, the MEMS resonator 110 is separated from the drive electrode 120 by gap 130 and from the sense electrode 122 by gap 132. Gaps 130 and 132, along with other suitable spaces between components provides for motion of the MEMS resonator, either laterally, vertically, rotationally, or the like as appropriate to the particular application.

Although a single MEMS resonator is illustrated in FIG. 1, embodiments of the present invention are not limited to a single device. Generally, an array of devices are fabricated on the substrate and wafer-level packaging is performed utilizing the techniques described herein. Subsequent dicing is used to separate individual devices. Moreover, although a MEMS resonator is illustrated in FIG. 1A and FIG. 1B, embodiments of the present invention are not limited to such resonators. Other MEMS structures are included within the scope of embodiments of the present invention.

Additional discussion related to MEMS resonators and MEMS oscillators is provided in commonly assigned and co-pending U.S. patent application Ser. No. 11/950,373, filed on Dec. 4, 2007, entitled “Method and Apparatus for MEMS Oscillator,” the disclosure of which is incorporated herein by reference in its entirety for all purposes.

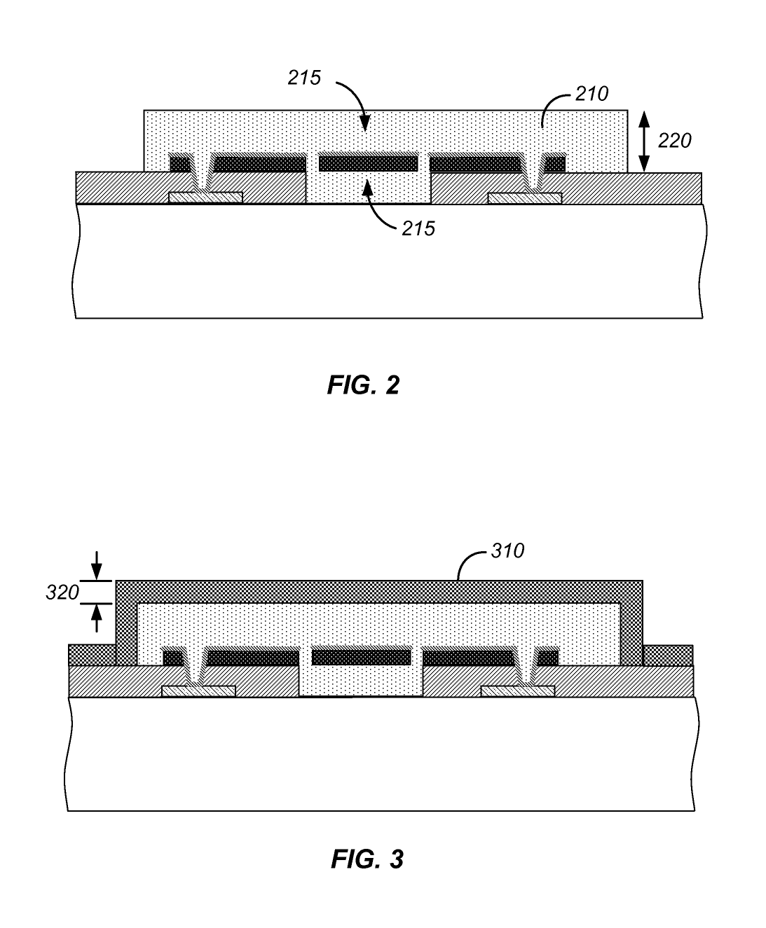

FIG. 2 is a simplified cross-sectional view of a MEMS package at a first stage of formation according to an embodiment of the present invention. In the embodiment illustrated in FIG. 2, an encapsulant material 210 (e.g., a sacrificial photoresist layer) is deposited and patterned to encapsulate the MEMS resonator and form a space or cavity region 215 surrounding the MEMS resonator when the encapsulant material is removed and/or evacuated in the subsequent fabrication steps. Other materials including organic materials that will provide mechanical support for subsequently formed layers and yet are removable during subsequent processing steps, as described more fully below, may also be used to form the encapsulating material layer illustrated in FIG. 2. Photoresist is utilized in some embodiments, since after development, photoresist provides sufficient mechanical rigidity and chemical resistance to support overlying deposited layers, yet is able to be removed using plasma ashing processes that selectively remove the photoresist without removing substantial portions of the overlying deposited layers.

Moreover, in embodiments in which the encapsulating material layer is formed using spin-on application techniques suitable for liquid materials, the top surface of the layer is substantially planar after formation. In other embodiments, planarization of the encapsulating material layer is performed after the spin-on application techniques are completed. Preferably, the planarized surface of layer 210 is characterized by a waviness, defined as a peak to valley roughness, of less than 50 nm. The planarity of layer 210 is referred to as substantially planar in some embodiments. In one embodiment, photoresist material is spun on substrate 105 with a first thickness. Partial exposure of the photoresist material using an exposure dose less than that needed to fully expose the photoresist material is performed. Accordingly, development of the partially exposed photoresist results in removal of an upper portion of the photoresist material, producing an encapsulating layer of a second or final thickness as illustrated in FIG. 2. As illustrated in FIG. 2, the encapsulating material layer coats and embeds the various components fabricated in previous processing steps.

The dimensions of the encapsulating layer are selected to provide sufficient vertical and lateral clearance to enable the MEMS structure to move during operation. Thus, the dimensions of the encapsulating layer will depend on the particular application. In particular embodiments, the thickness 220 of the encapsulating layer 210 ranges from about 0.5 μm to about 2.0 μm.

The encapsulating layer 210 illustrated in FIG. 2 is shown with a substantially planar top surface. However, this is not required by embodiments of the present invention. In some embodiments, structures which provide additional mechanical strength are utilized in place of or in combination with the structure shown in FIG. 2. As an example, pyramid shaped structures that utilize triangular features to increase the load bearing character of the encapsulating material are utilized. One of ordinary skill in the art would recognize many variations, modifications, and alternatives.

Although the formation of the encapsulating layer is referred to above as a first stage of formation, it will be evident to one of skill in the art that the illustrated embodiment is not limited to the literal first stage or processing step. For example, formation of the encapsulating layer including photoresist material as illustrated in FIG. 2 could include a number of processing steps such as a bottom anti-reflection coat step (BARC), a photoresist coat step, a top anti-reflection coat step (TARC), a pre-exposure bake step, exposure in a scanner, a post-exposure bake step, a develop step, and the like. Thus, the references to a “first stage,” a “second stage,” and the like are merely provided for reference and are not intended to limit embodiments of the present invention to a particular number of processing steps. One of ordinary skill in the art would recognize many variations, modifications, and alternatives.

FIG. 3 is a simplified cross-sectional view of a MEMS package at a second stage of formation according to an embodiment of the present invention. In the embodiment illustrated in FIG. 3, a first capping layer 310 (e.g., an amorphous silicon layer), also referred to as a sealant layer, is formed using a wafer-level blanket deposition process. Thus, a conformal coating having a thickness 320 of about 0.3 μm is formed as illustrated in FIG. 3. Other embodiments of the present invention utilize layers other than amorphous silicon to form the first capping layer, for example, polysilicon, silicon oxide, silicon nitride, metal, and the like. As described more fully throughout the present specification and more particularly below, the first capping layer 310 provides a mechanically and chemically stable capping layer that is resistant to removal during certain subsequent processing steps. The type of material and thickness of the capping layer is chosen in accordance with its lateral extent to have the required mechanical strength so that it can sustain a pressure difference of at least one atmosphere between the interior space 215 and the exterior space without being ruptured and/or collapsed. Thus, layers of appropriate thickness and material properties that are suitable as capping layers are included within the scope of embodiments of the present invention.

The deposition and patterning of the amorphous silicon layer illustrated in FIG. 3 is performed utilizing CMOS compatible deposition processes. That is, the process used to deposit and pattern layer 310 is performed in light of the structures associated with the CMOS device substrate. For example, some CMOS circuitry may be adversely impacted by performing high temperature deposition processes, as these high temperature deposition processes may damage metals (e.g., aluminum reflow) or result in diffusion of junctions associated with the CMOS circuitry. Thus, in a particular embodiment of the present invention, low temperature deposition, patterning, and etching processes, such as processes performed at temperatures of less than 500° C., are used to form layer 310. In another specific embodiment, deposition, patterning, and etching processes performed at less than 400° C., are used to form layer 310. Thus, the temperature at which the deposition and other processing is performed is generally characterized as a low temperature processes, thereby preserving CMOS structures on the substrate from temperature induced damage.

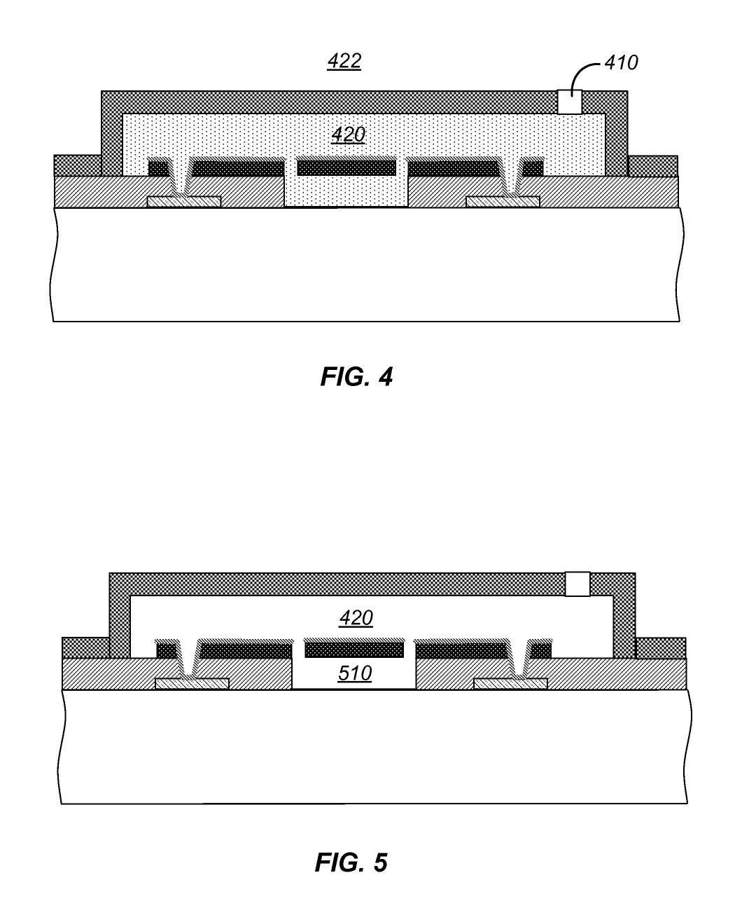

FIG. 4 is a simplified cross-sectional view of a MEMS package at a third stage of formation according to an embodiment of the present invention. The amorphous silicon layer 310 deposited in a previous step is patterned and then etched form release hole pattern 410. The formation of the release hole pattern 410 exposes a portion of the top layer of the photoresist layer 215 to processing fluids, including liquids and gases, utilized for subsequent processing steps. In the embodiment illustrated in FIG. 4, the release hole pattern is positioned laterally to the side of the MEMS resonator, but this is not required by embodiments of the present invention. As described below, the release hole pattern 410 illustrated in FIG. 4 is merely an example that enables description of the purpose and function of the release hole pattern.

The dimensions and shape of the release hole pattern 410 are selected to provide for passage of chemicals, liquids, and/or gases from the region surrounding the MEMS resonator located inside the region bounded by the amorphous silicon layer 310 to the region outside of the amorphous silicon layer 310. That is, the release hold pattern 410 provides for flow of fluids from region 420 to region 422 and vice versa. Thus, although only a single release hole pattern 410 is illustrated in FIG. 4, embodiments of the present invention are not limited to the illustrated shape or positioning. For example, depending on the embodiment, the release hole pattern 410 may be characterized by a number of geometries including a hole, a line, a series of lines, and the like. In some embodiments, multiple release hole patterns are formed at various portions of the layer 310 as appropriate to the structure of the MEMS resonator and the materials surrounding the MEMS resonator, for example, photoresist layer 215.

FIG. 5 is a simplified cross-sectional view of a MEMS package at a fourth stage of formation according to an embodiment of the present invention. As illustrated in FIG. 5, a plasma ashing process is used to remove the photoresist material encapsulating the MEMS resonator that was previously formed as illustrated in FIG. 2. Thus, the photoresist material 210 is typically referred to as sacrificial photoresist material. As shown in FIG. 5, the photoresist material in region 420 as well as region 510 is removed during these processing steps. The release hole pattern formed in the step illustrated in FIG. 4 is used to provide access to the sacrificial photoresist material in regions 420 and 510 during the removal process. As will be evident to one of skill in the art, the amorphous silicon layer 310 is substantially resistant to the plasma ashing process illustrated in FIG. 4. Accordingly, layer 310 retains its structural properties during the plasma ashing process and thereby maintains the moveable portions of the MEMS resonator free from contact with layer 310.

After the plasma ashing process, since the encapsulant material is removed, the MEMS resonator is free to move once again as appropriate to the particular application. In addition to plasma ashing, other suitable removal processes are included within the scope of embodiments of the present invention. The removal processes work in conjunction with the geometry of the release hole pattern(s) and the various gaps between components of the MEMS resonator. Multiple removal processes may be utilized in order to remove materials at different rates from different components of the structure in some embodiments. One of ordinary skill in the art would recognize many variations, modifications, and alternatives.

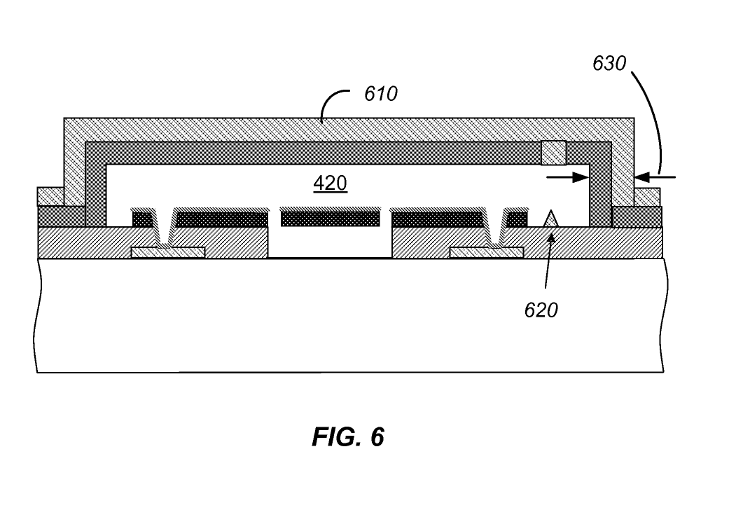

FIG. 6 is a simplified cross-sectional view of a MEMS package at a fifth stage of formation according to an embodiment of the present invention. A second capping layer 610 (e.g., an amorphous silicon layer) is blanket deposited on the substrate. The second amorphous silicon layer 610 encapsulates the first amorphous silicon layer 310 and fills the release hole pattern 410 previously formed. In some embodiments, a portion of the second amorphous silicon layer is deposited on the substrate as illustrated by the additional deposition 620 to the right of the MEMS resonator. Thus, in these embodiments, the positioning and geometry of the release hole pattern is selected to position any additional deposition at locations appropriate to the operation of the MEMS resonator. According to embodiments of the present invention, the placement of the release hole pattern is selected to minimize the impact of any additional deposition on the operation of the MEMS resonator.

Other embodiments of the present invention utilize layers other than amorphous silicon for the second capping layer 610, for example, polysilicon, silicon dioxide, silicon nitride, metal, or the like. Referring to FIG. 6, the second amorphous silicon layer 610 is also a conformal layer, although this is not required by the present invention. The conformal nature of layer 610 is modified in the illustrated embodiment by the presence of the release hole pattern, which is filled and sealed during the deposition process. Gettering structures (not illustrated) may be provided inside the finished package to getter materials present in the package after the formation of the second amorphous silicon layer. In some embodiments, the deposition processes utilized to form layer 610 result in a vacuum in region 420 adjacent the MEMS resonator. Thus, hermetic sealing of the MEMS resonator is provided in some embodiments, including the provision of a vacuum or reduced pressure atmosphere in region 420. In other embodiments, other atmospheres including inert gases, gases suitable for getter materials, or the like are utilized. Although a hermetic vacuum seal is contemplated herein, this is not required by embodiments of the present invention. Atmospheres appropriate to the operation of the MEMS resonator are provided depending on the particular application. One of ordinary skill in the art would recognize many variations, modifications, and alternatives.

The deposition of the second amorphous silicon layer may be performed using a low temperature (i.e., CMOS compatible) deposition process or a higher temperature process. In some higher temperature processes (e.g., deposition at temperatures greater than about 400° C.), contaminants in the vicinity of the MEMS resonator are baked out before and/or during deposition. In some embodiments, the environment used during the deposition of the second amorphous silicon layer is substantially a vacuum environment, resulting in the provision of a vacuum in region 420.

As illustrated in FIG. 6, embodiments of the present invention provide a hermetically sealed package for the MEMS resonator that is fabricated utilizing semiconductor processing techniques rather than conventional packaging techniques. The thickness of the walls of the packaging structure are therefore generally much thinner than the walls utilized in conventional packages. Accordingly, the spacing between adjacent devices can be reduced, thereby increasing packaging density and lowering device cost. In some embodiments, the thickness 630 of the walls of the packaging structure ranges from about 1.0 μm to about 10 μm. In a particular embodiment, the thickness 630 is about 5.0 μm. The thickness will depend on a variety of factors including the material utilized in forming layer 310 and 610, the atmospheric pressure in region 420, and the like.

Wafer level hermetic packaging of one or more MEMS structures with very compact form factors is provided by embodiments of the present invention. As described above, although a single MEMS structure is illustrated in FIG. 6, other embodiments include multiple MEMS structures in each package, multiple MEMS structures in separate packages, or combinations thereof.

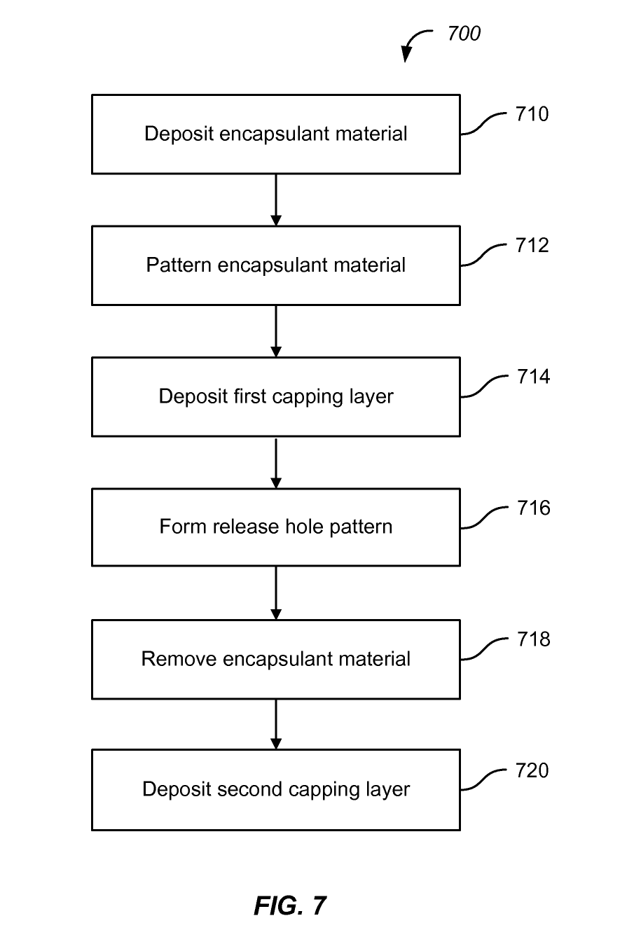

FIG. 7 is a simplified flowchart illustrating a method of fabricating a hermetically sealed package according to an embodiment of the present invention. The method 700 includes depositing an encapsulant material 710 (e.g., a photoresist layer) and patterning the encapsulant material 712 to form a number of MEMS resonators encapsulated in the encapsulating material. In a particular embodiment, a number of sacrificial photoresist structures are thus formed encapsulating one or more MEMS resonators previously formed on a CMOS wafer. The dimensions of the encapsulated structures (e.g., sacrificial photoresist structures) are selected to provide a cavity space surrounding each of the MEMS resonators while maintaining a relatively small distance between MEMS resonators. Thus, embodiments of the present invention provide for packages with compact form factors in comparison with other techniques. Additionally, the encapsulating structures provide mechanical support for subsequently formed capping layers, including layers of amorphous silicon. At the same time, the material utilized in forming the encapsulating structures is able to be selective removed with respect to one or more of the subsequently formed capping layers.

The method 700 also includes depositing a first capping layer 714 (e.g., an amorphous silicon layer) on the wafer. In a particular embodiment, the first capping layer is a conformal layer of amorphous silicon although other materials and geometries are included within the scope of embodiments of the present invention. The method further includes forming one or more release hole patterns in the first capping layer 716 and removing the encapsulant material 718 (e.g., patterned photoresist structures) using, for example, a plasma ashing process. The release hole patterns may have a variety of geometries and positions with respect to the MEMS resonator depending on the particular application. A second capping layer (formed, for example from an amorphous silicon layer) is deposited on the wafer 720. In the embodiment illustrated in FIG. 6, the second capping layer fills the one or more release hole patterns and hermetically seals the MEMS resonator. As described above, the atmosphere utilized in performing the deposition of the second capping layer is selected to provide either a vacuum atmosphere, a reduced pressure atmosphere including one or more fluids such as gases, or other suitable atmospheres. Gettering material may be utilized in the sealed device as appropriate to the particular application. One of ordinary skill in the art would recognize many variations, modifications, and alternatives.

It should be appreciated that the specific steps illustrated in FIG. 7 provide a particular method of forming a package for a MEMS structure according to an embodiment of the present invention. Other sequences of steps may also be performed according to alternative embodiments. For example, alternative embodiments of the present invention may perform the steps outlined above in a different order. Moreover, the individual steps illustrated in FIG. 7 may include multiple sub-steps that may be performed in various sequences as appropriate to the individual step. Furthermore, additional steps may be added or removed depending on the particular applications. One of ordinary skill in the art would recognize many variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method of forming a package for a MEMS structure coupled to a substrate, the method comprising:
depositing an encapsulant material on the substrate;
patterning the encapsulant material to form a plurality of encapsulated structures;
depositing a first capping layer on the substrate;
forming one or more release hole patterns in the first capping layer;
removing the encapsulant material; and
depositing a second capping layer.

2. The method of claim 1 wherein depositing the encapsulant material on the substrate comprises performing a spin coating process using a liquid encapsulant material.

3. The method of claim 2 wherein the encapsulant material comprises a photoresist material.

4. The method of claim 1 wherein the first capping layer comprises an amorphous silicon layer.

5. The method of claim 4 wherein the second capping layer comprises a second amorphous silicon layer.

6. The method of claim 1 wherein depositing the first capping layer comprises performing a low temperature deposition process characterized by a maximum process temperature less than 500° C.

7. The method of claim 1 wherein removing the encapsulant material comprises performing a plasma ashing process.

8. The method of claim 1 wherein the MEMS structure comprises a MEMS resonator.

9. The method of claim 1 wherein the substrate comprises CMOS circuitry.

10. The method of claim 1 wherein depositing the second capping layer comprises forming a hermetically sealed environment for the MEMS structure.

11. A package for a MEMS structure, the package comprising:
a MEMS structure coupled to a substrate;
a cavity region adjacent the MEMS structure and extending to a predetermined distance from the substrate;
a first sealant layer having a first portion joined to the substrate and a second portion disposed over the cavity region; and
a second sealant layer having a first portion joined to the first portion of the first sealant layer and a second portion joined to the second portion of the first sealant layer.

12. The package of claim 11 wherein the second portion of the first sealant layer is substantially planar.

13. The package of claim 11 wherein the second sealant layer further comprises a portion extending through the first sealant layer.

14. The package of claim 11 further comprising an inert environment in the cavity region.

15. The package of claim 14 wherein the inert environment comprises a vacuum environment.

16. The package of claim 11 further comprising a getter in fluid communication with the cavity region.

17. The package of claim 11 wherein the first sealant layer comprises an amorphous silicon layer.

18. The package of claim 11 wherein the second sealant layer comprises an amorphous silicon layer.

19. The package of claim 11 wherein the substrate comprises CMOS circuitry.

20. The package of claim 11 wherein the MEMS structure comprises a MEMS resonator.
